(19) United States
(12) Patent Application Publication
(10) Pub. No.: US 2005/0006726 A1
(43) Pub. Date: Jan. 13, 2005

(54) Apparatus and method for testing semiconductor nodules on a semiconductor substrate wafer

(75) Inventor: Peter Ossimitz, Munchen (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 10/855,945

(22) Filed: May 28, 2004

(30) Foreign Application Priority Data
May 30, 2003 (DE) 103 24 748.3
Apr. 1, 2003 (DE) 10 2004 015 937.8

(51) Int. Cl. H01L 23/544

(52) U.S. Cl. 257/620

(57) ABSTRACT

A method and an apparatus for testing semiconductor modules of a semiconductor substrate wafer are proposed, which can be used to increase a test economy. This is achieved by the semiconductor modules on the semiconductor substrate wafer being arranged centrosymmetrically relative to a geometrical center point in at least one region per half-wafer. Between placement operations of a needle card for testing the semiconductor modules, the semiconductor substrate wafer is rotated through a defined angle, as a result of which a test efficiency can be increased in an advantageous manner.

### TECHNICAL FIELD OF THE INVENTION

The invention relates to an apparatus and a method for testing semiconductor modules on a semiconductor substrate wafer.

### BACKGROUND OF THE INVENTION

During the highly parallel testing of semiconductor modules on a semiconductor substrate wafer, during which many of the semiconductor modules on the semiconductor substrate wafer are tested essentially simultaneously, approximately 100 to 10000 semiconductor modules may be tested in parallel nowadays in an individual test step, depending on the number of available test channels of a test system. This corresponds to the semiconductor substrate wafer being approximately half populated, depending on the type of module. In this case, a needle card with test arrays is used in order to make contact with and to test the individual semiconductor modules on the semiconductor substrate wafer by means of the needle card.

DE 101 30 977 A1 discloses a needle card for testing integrated circuits on a semiconductor substrate wafer, the needle card having a plurality of test arrays which are arranged on the needle card in accordance with an arrangement of the semiconductor modules to be tested on the semiconductor substrate wafer. In this case, the test arrays are arranged on the needle card in such a way that they also correspond to an arrangement of the integrated semiconductor modules at an edge region of the semiconductor substrate wafer, so that, after a placement of the needle card on the semiconductor substrate wafer, essentially needle sets of all the test arrays of the needle card make contact with assigned integrated semiconductor modules.

However, testing all the semiconductor modules on the semiconductor substrate wafer by means of the needle card shown in DE 101 30 977 A1 requires at least two differently designed needle cards which can increase a test outlay in a disadvantageous manner.

### SUMMARY OF THE INVENTION

The invention provides an apparatus and a method for improved testing of semiconductor modules on a semiconductor substrate wafer.

In one embodiment of the invention, there is a semiconductor substrate wafer having semiconductor modules arranged in matrix form on the semiconductor substrate wafer. In this case, the semiconductor substrate wafer is subdivided into at least two half-wafers, the semiconductor modules being arranged and oriented centrosymmetrically with respect to one another relative to a geometrical center point of the semiconductor substrate wafer in each case in at least one region of the two half-wafers.

Advantageously, the centrosymmetrical arrangement of the semiconductor modules that is present in the at least one region of the two half-wafers is that, in a test operation, after a rotation of the semiconductor substrate wafer through a defined angle, it is possible to use an individual needle card for testing the semiconductor modules with an essentially unchanged position relative to the semiconductor substrate wafer. The centrosymmetry according to the invention thus permits a reduction of a complicated horizontal relative movement(stepping) of the semiconductor substrate wafer with respect to the testing needle card to a simple rotation and can thereby contribute to a considerable improvement of test quality and economy of the semiconductor modules on the semiconductor substrate wafer.

In accordance with a preferred embodiment, the semiconductor substrate wafer is subdivided into four parts, the semiconductor modules being arranged and oriented centrosymmetrically with respect to one another relative to the geometrical center point of the semiconductor substrate wafer in each case in at least one region of the four quarter-wafers. It is furthermore preferred to design the semiconductor substrate wafer with regard to the stepping during the exposure operation such that at least one matrix of semiconductor modules which is arranged and oriented intrinsically symmetrically is provided for each region.

In another embodiment according to the present invention, there is a method for testing semiconductor modules on a semiconductor substrate wafer, in which the semiconductor modules are arranged in matrix form and the semiconductor substrate wafer is subdivided into two half-wafers, the semiconductor modules are arranged and oriented centrosymmetrically with respect to one another relative to a geometrical center point of the semiconductor substrate wafer in each case in at least one region of the two half-wafers, the following method steps are provided: placement of a needle card on the semiconductor substrate wafer for the purpose of testing the semiconductor modules in one region of one half-wafer, lifting-off of the needle card from the semiconductor substrate wafer, mutual rotation of the semiconductor substrate wafer through 180°, and placement of the needle card on the semiconductor substrate wafer for the purpose of testing the semiconductor modules in one region of the other half-wafer.

In an alternative embodiment according to the invention for testing semiconductor modules on a semiconductor substrate wafer, in which the semiconductor modules are arranged in matrix form, the semiconductor substrate wafer being subdivided into four quarter-wafers and the semiconductor modules being arranged and oriented centrosymmetrically with respect to one another relative to the geometrical center point of the semiconductor substrate wafer in each case in at least one region of the four quarter-wafers, the following method steps are employed: placement of a needle card on the semiconductor substrate wafer for the purpose of testing the semiconductor modules in the centrosymmetrically designed region of the first quarter-wafer, lifting-off of the needle card from the semiconductor substrate wafer, mutual rotation of semiconductor substrate wafer and needle card through 90°, placing the needle card on the semiconductor substrate wafer for the purpose of testing the semiconductor modules in the centrosymmetrically designed region of the second quarter-wafer and repeating the preceding steps with the centrosymmetrically designed regions of the quarter-wafers have been tested.

In a test system according to one embodiment of the invention, the needle card and/or the wafer holder are of rotatable design. In a needle card according to the invention, test arrays with needles are arranged and oriented in accordance with the centrosymmetrically designed region of the semiconductor components on the semiconductor substrate wafer.

For exposing a semiconductor substrate wafer according to the invention, use is made of a reticule having a designed plane in which is provided at least one matrix of semiconductor modules which are arranged and oriented intrinsically symmetrically. Preferably, the matrix in the design plane is composed of four semiconductor modules which are in each case arranged in oriented fashion in a manner rotated through 90° with respect to one another.

In the case of the methods according to the invention, the test apparatus according to the invention and the needle card according to the invention, an advantage afforded is that an individual needle card can be used to make contact with and test a plurality of semiconductor modules in a defined region per wafer part of the semiconductor substrate wafer with a needle card position method essentially unchanged relative to the semiconductor substrate wafer. The test efficiency can be significantly increased in this way.

### BRIEF DESCRIPTION OF THE DRAWINGS

The invention is described in detail below with reference to the figures, in which:

FIG. 1 shows a basic illustration of a conventional test operation of semiconductor modules on a semiconductor substrate wafer.

FIG. 2 shows a basic illustration of one preferred embodiment of a semiconductor substrate wafer with semiconductor modules according to the invention.

FIG. 3 shows a further preferred embodiment of the semiconductor substrate wafer according to the invention.

FIG. 4 shows a further preferred embodiment of the semiconductor substrate wafer according to the invention.

FIG. 5 shows a basic illustration of a semiconductor substrate wafer for which one embodiment of the method according to the invention can be used.

FIG. 6 shows a schematic illustration of a test system according to the invention having a needle card according to the invention.

### DETAILED DESCRIPTION OF THE INVENTION

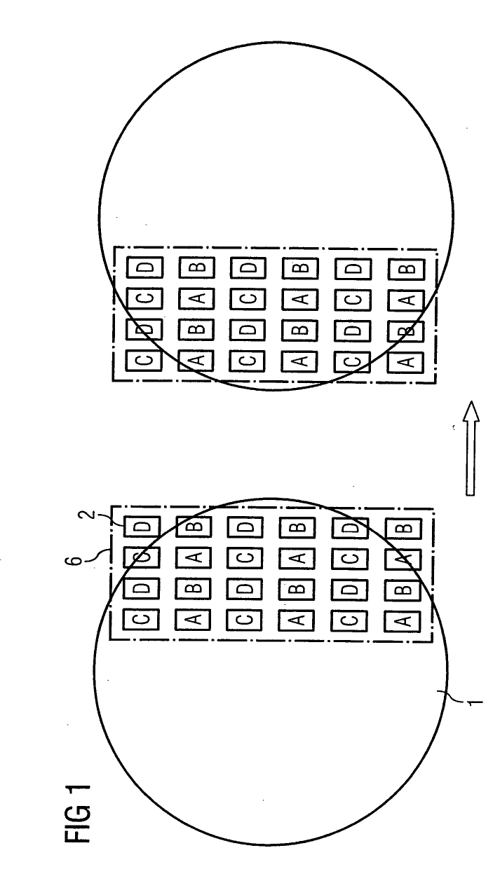

FIG. 1 shows a basic illustration of a conventional test operation of semiconductor modules on a semiconductor substrate wafer 1 with the aid of a needle card 6. The semiconductor substrate wafer 1 has a multiplicity of semiconductor modules (not illustrated in the figure). The needle card 6 comprises test arrays 2 with needles for testing the semiconductor modules on the semiconductor substrate wafer 1. The semiconductor modules on the semiconductor substrate wafer 1 can be tested while contact is made with the needles of the test arrays 2 of the needle card 6. FIG. 1 illustrates test arrays 2 grouped in a block-like manner, blocks of in each case four test arrays 2 (test arrays A to D) in each case being assigned to blocks of four semiconductor modules to be tested. It can be seen that, at a specific point in time when the needle card 6 is based on the semiconductor substrate wafer 1, a portion of the available test resources of the needle card 6 is utilized. In particular, some of the test arrays 2 are not utilized for example because they have not completely made contact with the assigned semiconductor modules.

The arrow illustrated in FIG. 1 indicates a relative movement between the semiconductor substrate wafer 1 and the needle card 6, the semiconductor substrate wafer 1 generally being movable relative to the needle card 6. This relative movement can give rise to a problem in that needles of test arrays 2 which are not actually required for testing are placed at the edge of the semiconductor substrate wafer 1, which, under certain circumstances, may lead to intensified wear of the needles of the test arrays 2. In addition, this also results in a disadvantage of intensified contamination of the needles of the unused test arrays 2.

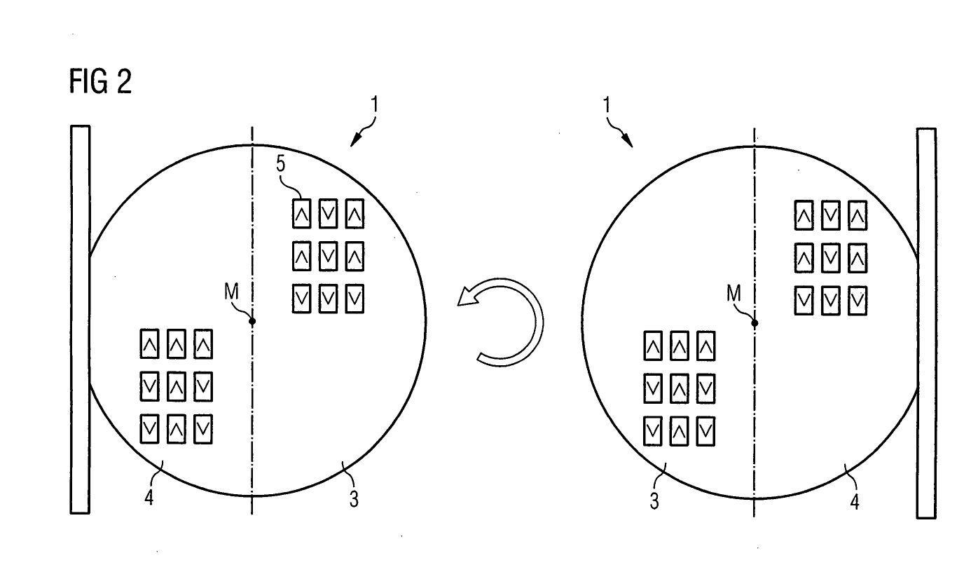

FIG. 2 shows an exemplary embodiment of a basic arrangement according to the invention of the semiconductor modules 5 on the semiconductor substrate wafer 1, the arrow in each case specifying the orientation of the semiconductor modules 5. In this case, the semiconductor modules 5 on the semiconductor substrate wafer 1 are arranged and oriented centrosymmetrically relative to a geometrical center point M of the semiconductor substrate wafer 1 in at least one region of two half-wafers 3, 4 of the semiconductor substrate wafer 1.

The arrangement of the semiconductor modules 5 on the half-wafers 3, 4 of the semiconductor substrate wafer 1 as illustrated in the figure means that the semiconductor modules 5 which are arranged and oriented centrosymmetrically with respect to one another can have contact made with them and be tested in two placement operations (as touch-downs) with essentially unchanged placement positions of the needle card 6. In this case, the semiconductor modules 5 which are arranged and oriented centrosymmetrically on the first half-wafer 3 of the semiconductor substrate wafer 1 are tested in a first placement operation of the needle card 6 on the first half-wafer 3. The test arrays 2 with the needles of the needle card 6 encompass the testing of the semiconductor modules on the semiconductor substrate wafer 1. This is followed by a lifting-off of the needle card from the semiconductor substrate wafer 1 and a mutual rotation of semiconductor substrate wafer 1 and needle card 6 thorugh 180°. The needle card 6 is then placed onto the second half-wafer 4 of the semiconductor substrate 1 in order to make contact with and to test the semiconductor modules 5 of the semiconductor substrate wafer 1 that are arranged centrosymmetrically in the second half-wafer 4.

In this case, it is regarded as particularly advantageous that the test economy can be significantly improved as a result of an interaction of the rotation according to the invention of the semiconductor substrate wafer 1 with respect to the needle card 6 between the individual placement operations of the needle card 6 and a correspondence between the geometrical arrangement of the test arrays 2 of the needle card and the semiconductor modules 5 to be tested on the semiconductor substrate wafer 1. This may result for example in a significantly increased throughput of tested semiconductor substrate wafers 1 in comparison with the conventional test methods. A relative movement—required in the conventional test methods—in the x-y direction between the semiconductor substrate wafer 1 and the needle card 6 between the individual placement operations is not necessary. Furthermore, this advantageously supports a deterministic connection of reference points (for example pads of the semiconductor modules 5 to be tested) to corresponding needles on the test arrays 2 of the needle card.

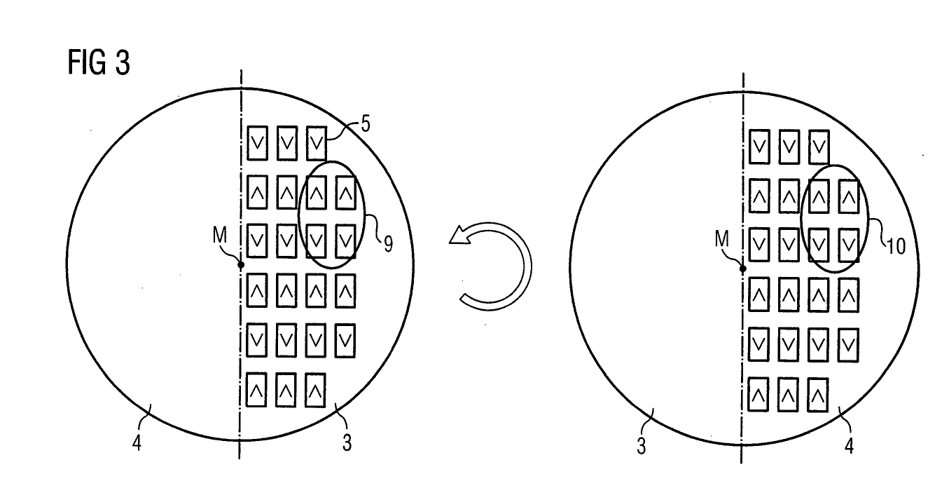

FIG. 3 shows a further exemplary embodiment of the arrangement according to the invention of the semiconductor modules 5 in the two half-wafers 3, 4 of the semiconductor substrate wafer 1. In this case, the semiconductor modules 5 are in each case arranged in a manner rotated through 180° row-wise on the two half-wafers 3, 4. As an illustration, the figure shows only the semiconductor modules 5 in the individual half-wafers 3, 4. The geometrical orientations of the semiconductor modules 5 are indicated by arrows in the semiconductor modules 5. The row-wise rotation of the semiconductor modules 5 through 180° in each case advantageously makes it possible to test the semiconductor modules 5 of the two half-wafers 3, 4 in just two placement operations of the needle card 6. Consequently, the semiconductor modules 5 of the semiconductor substrate wafer 1 can be tested with the aid of the two placement operations.

A central concept according to the invention is fulfilled in this embodiment, too, insofar as the semiconductor modules 5 are arranged centrosymmetrically with respect to one another relative to the geometrical center point M in at least one region of the two half-wafers 3, 4.

The test arrays 2 of the needle card 6 are geometrically oriented such that their orientation corresponds to an orientation of the centrosymmetrically arranged semiconductor modules 5 on the semiconductor substrate wafer 1 before a placement operation. Furthermore, an arrangement of the test arrays 2 on the needle card 6 can essentially be adapted to a peripheral form of the semiconductor substrate wafer 1. This affords an advantage that one complete half of all the semiconductor modules 5 of the semiconductor substrate wafer 1 can be tested in an individual placement operation of the needle card 6.

FIG. 3 reveals that a plurality of so-called reticule blocks, 9, 10 of semiconductor modules 5 are arranged per half-wafer 3, 4, the semiconductor modules 5 being arranged and oriented in a specific symmetrical form with respect to one another in each of the reticule blocks 9, 10. This symmetry within the reticule blocks 9, 10 is attributable to requirements during the exposure of the semiconductor substrate wafer 1 in the course of a production process. It can be seen that the symmetries within the reticule blocks 9, 10 in each case comprise a twin symmetry. This means that symmetrical structures (rows, columns) of the reticule blocks 9, 10, at their outer sides, in each case have to be paired or have multiples of two semiconductor modules 5. In an advantageous manner, it is thus possible to utilize the symmetry within the reticule blocks 9, 10 for the arrangement according to the invention of the semiconductor modules 5 on the semiconductor substrate wafer 1.

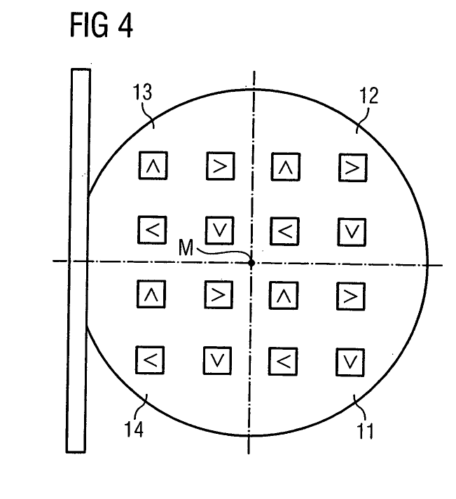

FIG. 4 shows a further preferred embodiment of the semiconductor substrate wafer 1 according to the invention. In this case, the semiconductor substrate wafer 1 is subdivided into four quarter-wafers 11, 12, 13, 14 in which case, in each of the four quarter-wafers 11, 12, 13, 14, in each case four semiconductor modules 5 are arranged and oriented centrosymmetrically relative to the geometrical center point M of the semiconductor substrate wafer 1 in at least one region.

The geometrical orientations of the semiconductor modules 5 are again indicated by arrows in the semiconductor modules 5. Furthermore, the four semiconductor modules 5 that are arranged centrosymmetrically in each of the four quarter-wafers 11, 12, 13, 14 are in each case arranged in oriented fashion in a manner rotated through 90° with respect to one another. Therefore, for exposing the semiconductor substrate wafer, use is made of reticule blocks having a design plane in which is provided at least one matrix of four semiconductor modules which are in each case arranged in oriented fashion in a manner rotated through 90° with respect to one another. On account of requirements during the exposure of the semiconductor substrate wafer 1, the semiconductor modules 5 are essentially of square design in this embodiment.

This embodiment of the arrangement according to the invention of the semiconductor modules 5 advantageously affords the possibility of using the needle card 6 after a rotation of the semiconductor substrate wafer 1 through 90° in each case, with an essentially constant placement position for the four quarter-wafers 11, 12, 13, 14, for testing the semiconductor modules 5 that are arranged centrosymmetrically in the four quarter-wafers 11, 12, 13, 14. Testing all the semiconductor modules 5 that are arranged centrosymmetrically in the four quarter-wafers 11, 12, 13, 14 in this case requires quadruple rotation of the semiconductor substrate wafer 1 and the needle card 6 with respect to one another through 90° in each case. The arrangement of four semiconductor modules 5 per quarter-wafer 11, 12, 13, 14 as shown in the figure is to be understood as illustrating the principle. It goes without saying that significantly more semiconductor modules 5 can be arranged centrosymmetrically per quarter-wafer 11, 12, 13, 14.

The embodiment of the semiconductor substrate wafer 1 according to the invention as illustrated in FIG. 4 advantageously enables test resources to be reduced. The geometrical adaptation of needle card and arrangement of test arrays which is possible according to the invention means that the test arrays can be utilized.

The arrangement according to the invention of the semiconductor modules 5 on the semiconductor substrate wafer 1 is thus characterized by the fact that an angle of rotation of the semiconductor substrate wafer 1 in the course of testing the semiconductor modules 5 between the individual placement operations essentially corresponds to a geometrical angle of orientation of the semiconductor modules 5 relative to the angle of rotation.

In the embodiment of FIG. 2 or 3, this principle means that the angle of rotation of the semiconductor substrate wafer of 180° corresponds to the geometrical angle of orientation of 180° of the semiconductor modules 5 in at least one region of the two half-wafers 3, 4. In the embodiment of FIG. 4, this means that the angle of rotation of the semiconductor substrate wafer of 90° corresponds to the geometrical angle of orientation of 90° of the semiconductor modules 5 in at least one region of the four quarter-wafers 11, 12, 13, 14.

Such a relation between the angle of rotation of the semiconductor substrate wafer 1 between the individual contact-making operations of the needle card 6 and the geometrical angle of orientation of the semiconductor modules 5 thus ensures the centrosymmetry according to the invention.

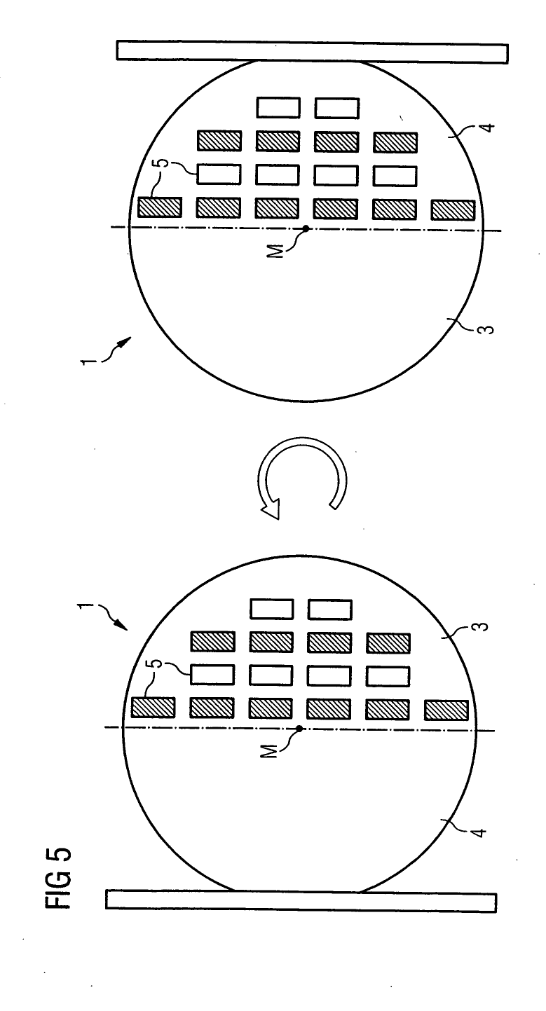

FIG. 5 shows an embodiment of the semiconductor substrate wafer 1 for which an embodiment of the method according to the invention can be employed. In this case, a plurality of placement operations of the needle card 6 per half-wafer 3, 4 are provided for testing the semiconductor modules 5. In the figure, the multiple placement per half-wafer 3, 4 is indicated by hatching of the semiconductor modules 5 with which contact is made in different placement steps. In this case, the hatched semiconductor modules 5 are tested in a first placement operation per half-wafer 3, 4, and the unhatched semiconductor modules 5 are tested in a second placement operation per half-wafer 3, 4. A translational relative movement between the semiconductor substrate wafer 1 and the testing needle card 6 (not illustrated in FIG. 5) is necessary between the individual placement operations per half-wafer 3, 4. Even further contact-making operations of the needle card 6 could be provided per half-wafer 3, 4.

This embodiment of the method according to the invention can advantageously be employed principally for semiconductor substrate wafers 1 having a number of semiconductor modules 5 which exceed test resources of the testing needle card 6. By way of example, a testing needle card 6 may have only 200 test channels together with assigned test resources (power supply units, analog test instruments) but 400 semiconductor modules 5, for example, may be arranged on a half-wafer 3, 4. It goes without saying that this preferred embodiment of the method according to the invention can also be employed for the semiconductor substrate wafer 1 illustrated in FIG. 4. This means that a plurality of placement operations of the testing needle card 6 are then provided in a test operation per quarter-wafer 11, 12, 13, 14.

In the case of the present invention, the test economy is advantageously supported by virtue of the fact that the orientation of the test arrays 2 of the needle card 6 is adapted to an orientation or arrangement of the semiconductor modules 5 on the two half-wafers 3, 4 of the semiconductor substrate wafer 1. As a result, after the placement operations of the needle card 6, contact connection location positions of the semiconductor modules 5 to be tested correspond essentially exactly to the needles of the test arrays 2 of the needle card.

Furthermore, the problem—known in the prior art—of placement of the needles of the test arrays 2 of the needle card 6 at the edge of the semiconductor substrate wafer 1 can be largely eliminated. Moreover, a geometrical relation between a wafer holder (chuck) of the semiconductor substrate wafer 1 and the needle card 6 can remain essentially unchanged as a result of the arrangement according to the invention of the semiconductor modules 5. As a result, a thermal radiation energy of the semiconductor substrate wafer 1 during a wafer hot measurement of the semiconductor substrate wafer 1 expediently acts uniformly on the testing needle card 6. This reduces an undesirable thermally governed curvature of the needle card 6 on account of non-uniform heating and thus contributes to a constant plurality of the needles of the needle card 6 and, as a result, to a uniform measurement quality.

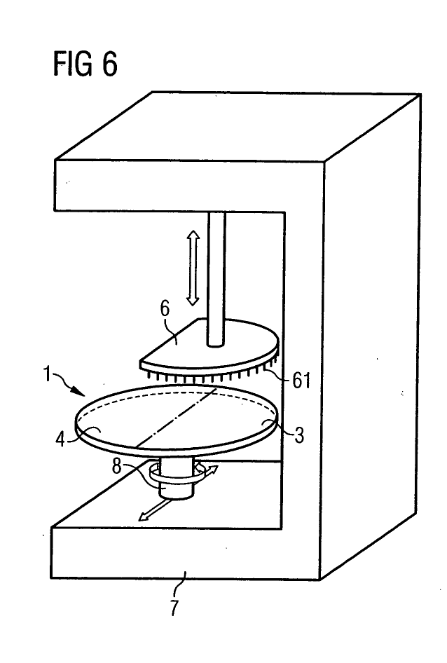

FIG. 6 shows a schematic illustration of a test system according to the invention with a half-disk shaped needle card 6 for testing a semiconductor substrate wafer 1 with semiconductor modules 5 in accordance with FIGS. 2 and 3. On a test device 7, the semiconductor substrate wafer 1 is mounted such that it can be rotated and displaced on a wafer holder 8. The semiconductor substrate wafer 1 is subdivided into the two half-wafers 3, 4 which have contact made with them and are tested by the half-disk-shaped needle card 6 after corresponding rotations through 180° in successive placement operations by means of the needles 61.

For this purpose, the needle card 6 is arranged such that it can be moved vertically at the test device 7, so that the needle card 6 makes contact with and tests the semiconductor modules 5 of the first half-wafer 3 in the first placement operation. This is followed by a lifting-off of the needle card 6 and a rotation of the semiconductor substrate wafer 1 through an angle of 180°. The semiconductor modules 5 in the second half-wafer 4 of the semiconductor substrate wafer 1 are then tested by means of the needle card 6.

For the testing of a semiconductor substrate wafer 1 in accordance with the embodiment in FIG. 4, where the angle of rotation is 90°, the needle card is preferably of quarter-circle-shaped design in order to make contact with at least the one centrosymmetrically designed region of the four quarter-wafers 11, 12, 13, 14 of the semiconductor substrate wafer 1.

In a further production step subsequent to the method according to the invention for the semiconductor modules 5, the semiconductor modules 5 are mounted in a housing (not shown). In this case, the geometrical orientation of the semiconductor modules 5 on the semiconductor substrate wafer 1 as used in the preceding test operation can continue to be used for the final orientation of the semiconductor modules 5 in the corresponding housings. A possible additional geometrical orientation of the semiconductor modules 5 for fixing in the housings can thus advantageously be obviated.

The aspects which are disclosed in the preceding description, the subsequent patent claims and the figures may be essential to the invention both individually and in any desired combination.

1. A semiconductor substrate wafer, comprising:
semiconductor modules, the semiconductor modules arranged in matrix form on the semiconductor substrate wafer, wherein
the semiconductor substrate wafer is subdivided into two half-wafers and the semiconductor modules are arranged and oriented centrosymmetrically with respect to one another relative to a geometrical center point of the semiconductor substrate wafer in each case in at least one region of the two half-wafers.

2. The semiconductor substrate wafer as claimed in claim 1, wherein the semiconductor substrate wafer is subdivided into four parts, the semiconductor modules arranged and oriented centrosymmetrically with respect to one another relative to the geometrical center point of the semiconductor substrate wafer in each case in at least one region of the four quarter-wafers.

3. The semiconductor substrate wafer as claimed in claim 1, wherein at least one matrix of the semiconductor modules which is arranged and oriented intrinsically symmetrically is provided for each region.

4. The semiconductor substrate wafer as claimed in claim 3, wherein the matrix comprises four semiconductor modules which are in each case arranged in oriented fashion in a manner rotated through 90° with respect to one another.

5. A method for testing semiconductor modules on a semiconductor substrate wafer, the semiconductor modules arranged in matrix form on the semiconductor substrate wafer and the semiconductor substrate wafer subdivided into two half-wafers and the semiconductor modules arranged and oriented centrosymmetrically with respect to one another relative to a geometrical center point of the semiconductor substrate wafer in each case in at least one region of the two half-wafers, comprising:
placing a needle of a needle card on the semiconductor substrate wafer for of testing the semiconductor modules in the centrosymmetrically designed region of one half-wafer;
lifting-off of the needle card from the semiconductor substrate wafer;
mutually rotating the semiconductor substrate wafer and needle card through 180°; and
placing the needle of the needle card on the semiconductor substrate wafer for testing the semiconductor modules in the centrosymmetrically designed region of the other half-wafer.

6. A method for testing semiconductor modules on a semiconductor substrate wafer, the semiconductor modules arranged in matrix form on the semiconductor substrate wafer and the semiconductor substrate wafer subdivided into four quarter-wafers, the semiconductor modules arranged and oriented centrosymmetrically with respect to one another relative to the geometrical center points of the semiconductor substrate wafer in each case in at least one region of the four quarter-wafers, and the semiconductor modules in each case being arranged at an angle of 90° with respect to one another in the regions of the four quarter-wafers of each half-wafer, comprising:
placing a needle card on the semiconductor substrate wafer for testing the semiconductor modules in the centrosymmetrically designed region of the first quarter-wafer;
lifting-off of the needle card from the semiconductor substrate wafer;
mutually rotating the semiconductor substrate wafer and needle card through 90°;
placing the needle card on the semiconductor substrate wafer for testing the semiconductor modules in the centrosymmetrically designed region of the second quarter-wafer; and
repeating lifting-off, mutually rotating and placing until the centrosymmetrically designed regions of the quarter-wafers have been tested.

7. The method as claimed in claim 5, wherein each placement of the needles of the needle card comprises at least two placement operations, a translational movement between the semiconductor substrate wafer, and the needle card piece being carried out between the at least two placement operations of the needle card.

8. A test system having a needle card and a wafer holder, comprising:
placing a needle of the needle card on the semiconductor substrate wafer for of testing the semiconductor modules in the centrosymmetrically designed region of one half-wafer;
lifting-off of the needle card from the semiconductor substrate wafer;
mutually rotating the semiconductor substrate wafer and needle card through 1800; and
placing the needle of the needle card on the semiconductor substrate wafer for testing the semiconductor modules in the centrosymmetrically designed region of the other half-wafer, wherein
the needle card and/or the wafer holder are of rotatable design.

9. A needle card for testing a semiconductor substrate wafer as claimed in claim 1,
wherein test arrays with needles are arranged and oriented in accordance with the centrosymmetrically designed regions of the semiconductor components on the semiconductor substrate wafer.

10. A reticule for exposing a semiconductor substrate wafer as claimed in one of claims 1,
wherein at least one matrix of semiconductor modules which are arranged and oriented intrinsically symmetrically is provided in a design plane.

11. The reticule as claimed in claim 10, wherein the matrix in the design plane comprises four semiconductor modules which are in each case arranged in oriented fashion in a manner rotated through 90° with respect to one another.
